(19) United States
(12) Patent Application Publication
(10) Pub. No.: US 2012/0061129 A1
(43) Pub. Date: Mar. 15, 2012

(54) CIRCUIT BOARD STRUCTURE WITH LOW CAPACITANCE

(76) Inventors: Ying-Jiunn Lai, Pingtung County (TW); Shih-Ming Chen, Changhua County (TW); Tzu-Wei Yeh, Taipei City (TW)

(21) Appl. No.: 12/883,169

(22) Filed: Sep. 15, 2010

(51) Int. Cl. H05K 1/00; H05K 1/09

(52) U.S. Cl. 174/257; 174/261

(57) ABSTRACT

A circuit board structure, comprising: a first metal layer, including at least one cavity; and a plurality of first pads, for connecting at least one differential signal transmission line; wherein at least part of a vertical projection of the first pad, which is projected on the first metal layer, is overlapped with the cavity.

### BACKGROUND OF THE INVENTION

1. Field of the Invention

The present invention relates to a circuit board structure, and particularly relates a circuit board structure that can provide low capacitance when it is connected to a connector.

2. Description of the Prior Art

FIG. 1 illustrates how a circuit board is welded to a connector, in the prior art. In this case, the circuit board 103 is welded to an SMD (Surface Mount Device) connector 101 with pins welded to a surface layer of the circuit board 103, via surface welding technology. Accordingly, when the circuit board 103 is layout, suitable pads (or named footprints) are provided as welding interface between the SMD connector 101 and the circuit board 103, according to the contact interface required by the pins. The characteristic impedance for the transmission line on the circuit board 103 can be controlled by different transmission line widths and substrate height. However, the SMD connector 101 presents conductance characteristic with high impedance for a signal transmission line of a single end channel. In order to avoid such characteristic causing multi-reflection for the transmission signal in the channel, many related invention provides low impedance capacitance loading to the pad. By this way, inductance/capacitance conjugate cancellation can be acquired to reach excellent impedance control. For example, American patent with patent numbers disclose such technique.

However, a single end signal has low noise reduction ability for the channel noise. Accordingly, differential signal transmission such as SATA, PCIe, USB are commonly utilized for high speed transmission protocol. However, differential impedance is not sure to be high impedance, and differential signal transmission line may cause mutual inductance effect to each other. Equation 1 indicates the differential impedance Z_{diff} of the SMD connector 101. Ls and Lm respectively indicate the self inductance and the mutual inductance of the SMD connector 101, Cs and Cm are respectively the self capacitance and the mutual capacitance of the SMD connector 101. Normally, Ls and Cs are constant values, such that Z_{diff} is inversely proportion to Lm and Cm. Therefore, the impedance of the SMD connector 101 will be different corresponding to different design and coupling methods. Thus, prior art can not well control impedance variation of the differential channel.

$${Z}_{diff} = 2 * \sqrt{\frac{{L}_{s} - {L}_{m}}{{C}_{s} + {C}_{m}}} \qquad Equation 1$$

Besides, the capacitance value is an important parameter when the signal is transmitted. FIG. 2 illustrates the capacitance value when the signal is transmitted between the circuit board and the connector, in the prior art. As shown in FIG. 2, different capacitance values are distributed between the connector, the connector pad, the circuit board and the package. Different return loss is caused corresponding to different capacitance value when the signal is transmitted. Accordingly, desired return loss is hard to be acquired when high capacitance exists.

### SUMMARY OF THE INVENTION

One embodiment of the present invention discloses a circuit board structure, comprising: a first metal layer, including at least one cavity; and a plurality of first pads, for connecting at least one differential signal transmission line; wherein at least part of a vertical projection of the first pad, which is projected on the first metal layer, is overlapped with the cavity.

Another embodiment of the present invention discloses a circuit board structure, comprising: a first metal layer, including at least one low capacitance region; and a plurality of first pads, for connecting at least one differential signal transmission line; wherein at least part of a vertical projection of the first pad, which is projected on the first metal layer, is overlapped with the low capacitance region.

Via above-mentioned embodiments, the capacitance of the connection point for the connector an the circuit board can be decreased.

These and other objectives of the present invention will no doubt become obvious to those of ordinary skill in the art after reading the along detailed description of the preferred embodiment that is illustrated in the various figures and drawings.

### BRIEF DESCRIPTION OF THE DRAWINGS

FIG. 1 illustrates how a circuit board is welded to a connector, in the prior art.

FIG. 2 illustrates the capacitance value when the signal is transmitted between the circuit board and the connector, in the prior art.

FIG. 3 illustrates a circuit board structure according to a first embodiment of the present invention.

FIG. 4 (a), FIG. 4 (b), FIG. 5, FIG. 6 respectively illustrates cross section view diagrams of the circuit board structure.

FIG. 7 illustrates a circuit board structure according to a second embodiment of the present invention.

FIG. 8 (a), FIG. 8 (b), FIG. 9 (a) and FIG. 9 (b) respectively illustrates cross section view diagrams of the circuit board structure shown in FIG. 7.

FIG. 10 illustrates a circuit board structure 1000 according to a third embodiment of the present invention.

FIGS. 11 (a), 11 (b) illustrate the cross section view diagram of the circuit structure shown in FIG. 10.

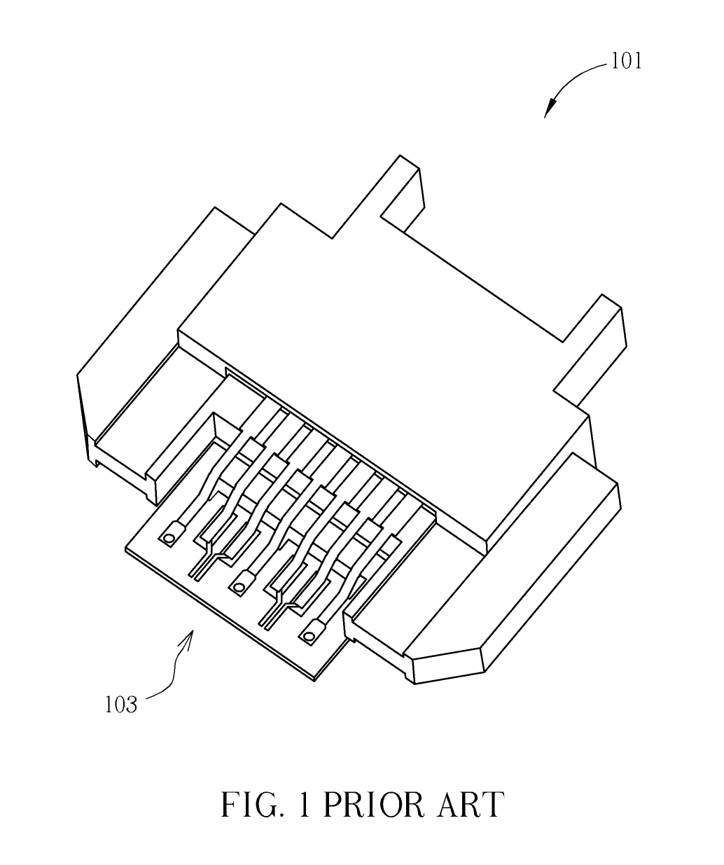

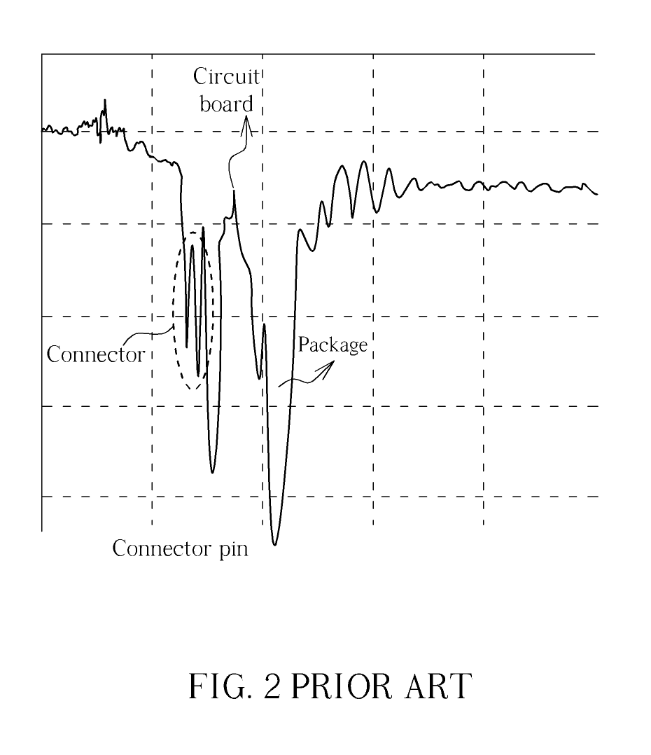

### DETAILED DESCRIPTION

Certain terms are used throughout the description and along claims to refer to particular components. As one skilled in the art will appreciate, electronic equipment manufacturers may refer to a component by different names. This document does not intend to distinguish between components that differ in name but not function. In the along description and in the claims, the terms “include” and “comprise” are used in an open-ended fashion, and thus should be interpreted to mean “include, but not limited to . . .”. Also, the term “couple” is intended to mean either an indirect or direct electrical connection. Accordingly, if one device is coupled to another device, that connection may be through a direct electrical connection, or through an indirect electrical connection via other devices and connections.

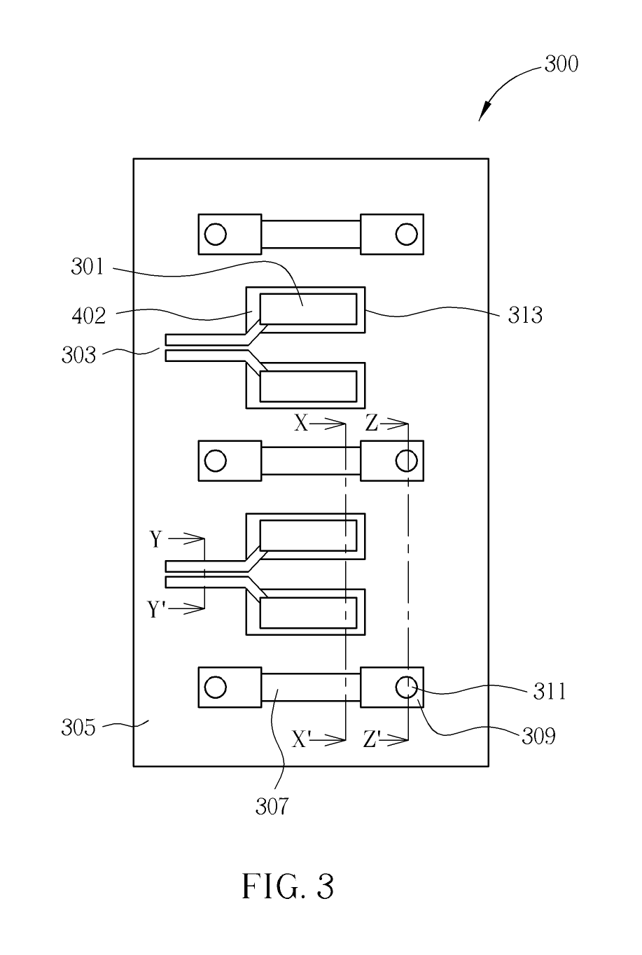

FIG. 3 illustrates a circuit board structure 300 according to a first embodiment of the present invention. The circuit board structure 300 includes a plurality of pads 301, differential signal lines 303, a first grounding copper foil 305, a grounding welding point 307, a grounding pad 309 (i.e. above mentioned footprint), and a contact 311. Additionally, the circuit board structure 300 further includes a cavity 313. Detail structure relation of these devices will be described hereafter. The pad 301 is coupled to the differential signal lines 303, and the layout layer thereof, which is normally regarded as a signal line layer, locates at a surface copper foil of a PCB (printed circuit board). The impedance of the differential signal lines 303 can be between 80-100 ohn, thus a grounding plane thereof can be a copper foil under the signal layer, that is, the first grounding copper foil 305. The grounding welding point 307 is a grounding footprint/pad of a connector. The grounding welding point 307 couples a connector grounding signal and the first grounding copper foil 305, via the grounding pad 309 and the contact 311, to make a grounding level of the circuit board the same with which of the connector.

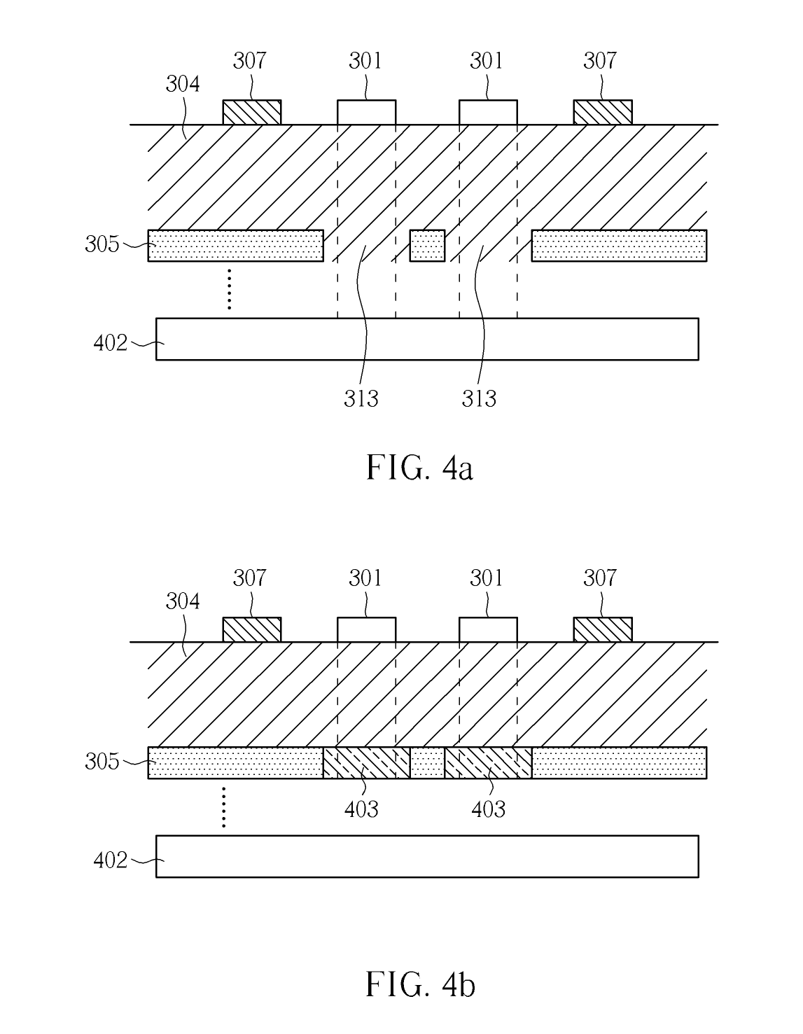

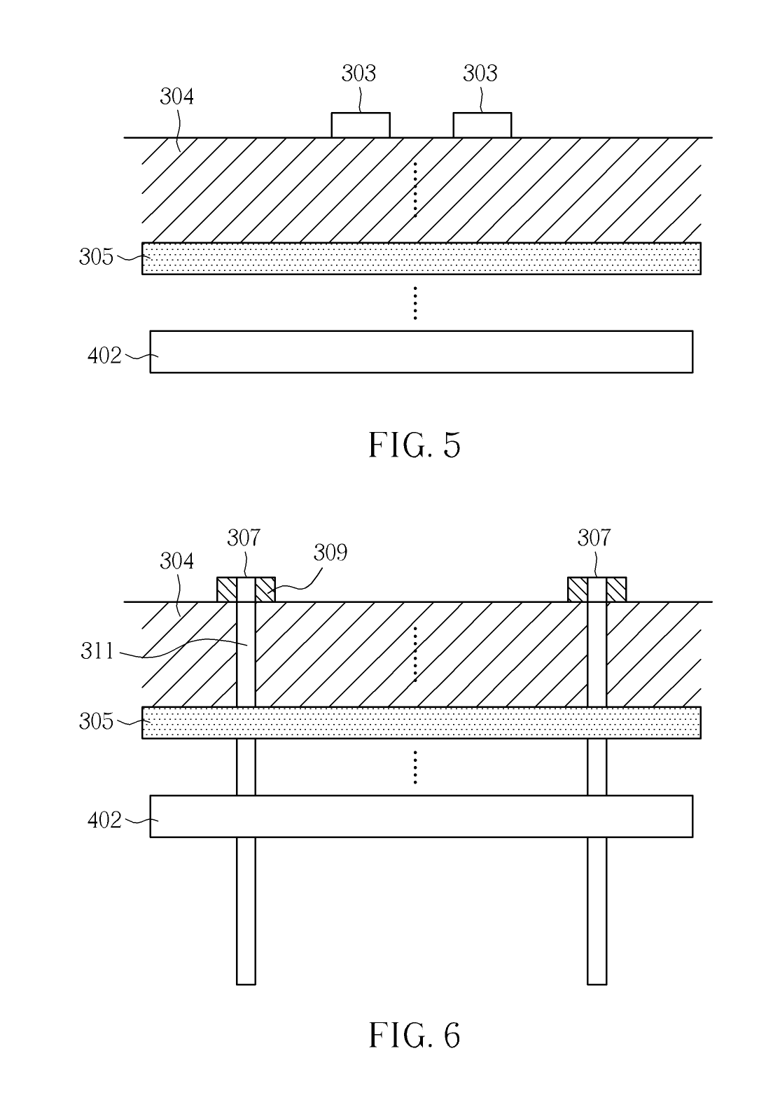

FIG. 4 (a), FIG. 4 (b), FIG. 5, FIG. 6 respectively illustrates cross section view diagrams of the circuit board structure 300. FIGS. 4 (a) and 4 (b) illustrate a cross section view along the X direction, FIG. 5 illustrates a cross section view along the Y direction, and FIG. 6 illustrates a cross section view along the Z direction. As shown in FIG. 4 (a) , the pad 301 and the grounding welding point 307 are above the first grounding copper foil 305, and a part of the first grounding copper foil 305 is removed torm the cavity 313. In the embodiment shown in FIG. 4 (a), the cavity 313 is just under the pad 301 and has a region larger than which of the pad 301. Accordingly, if looks down at the embodiment shown in FIG. 3, the pad 301 is above the cavity 313. Alternatively, it can be presented that a vertical projection of the first pad 301, which is projected on the first grounding copper foil 305, is included by the cavity 313. Besides, non conductive material 304 can be filled into the cavity 313 and filled between the pad 301 and the grounding welding point 307. Besides the first grounding copper foil 305, the circuit board structure 300 can further comprise a second grounding copper foil 402, such that the grounding layer can be changed corresponding to different circuit design. Via above mentioned structures, the capacitance value near the pad 301 can be decreased, such that desired return loss can be acquired. Besides utilizing the cavity 313 to decrease capacitance, the cavity 313 can be filled with other material to form a low capacitance region 403, as shown in FIG. 4 (b). The low capacitance region 403 can decrease the capacitance near the pad 301, the same as the cavity 313. Additionally, the non conductive material 304 can be filled into a space between the pad 301, the grounding welding point 307, the first grounding copper foil 305 and the low capacitance region 403. For example, material of the low capacitance region 403 can be chemical compounds FR-5, FR-4 and R04003, which are composed of epoxy resin, phenolic resin, paraformaldehyde, silicone and Teflon, and can be enhance by glass fiber, insulation paper and linen.

FIG. 5 is a cross section view of the circuit board 300 along the Y axis. As shown in FIG. 5, the differential signal line 303 is above the first grounding copper layer 305, the second grounding copper layer 402 and the non conductive material 304. FIG. 6 is a cross section view of the circuit board 300 along the Z axis. As shown in FIG. 6, the grounding pad 309 is connected to the first grounding copper layer 305 via the contact 311. Therefore, the connector is coupled to the first grounding copper layer 305 as well when it is coupled to the grounding pad 309, and the ground level of the connector and the circuit board 300 will be at the same level. If the circuit board 300 further comprise the second grounding copper layer 402, the contact 311 also makes the second grounding copper layer 402 electrically coupled to the differential signal line 303 and the first grounding copper layer 305.

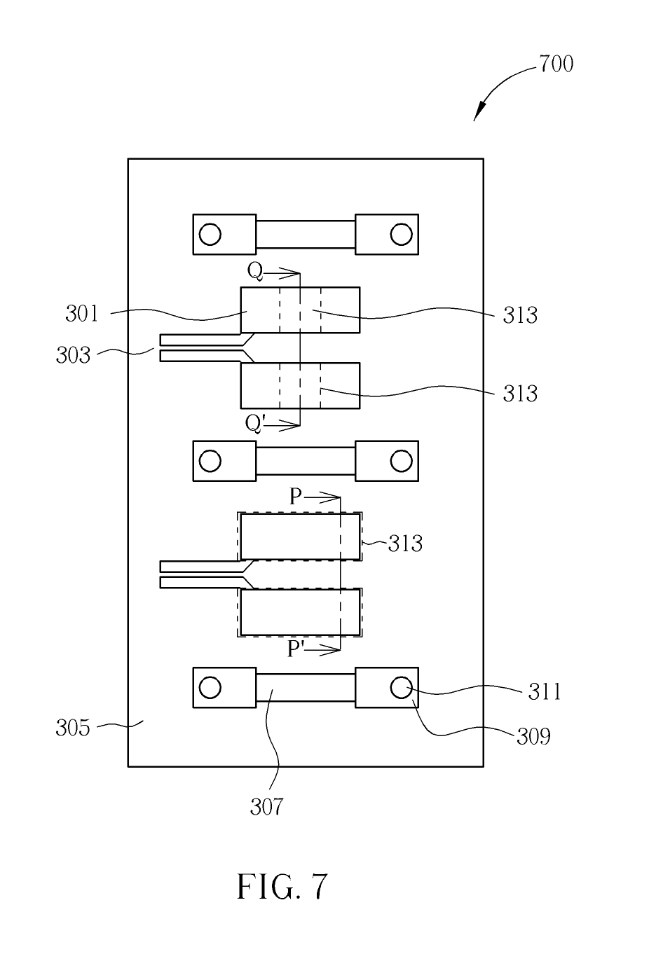

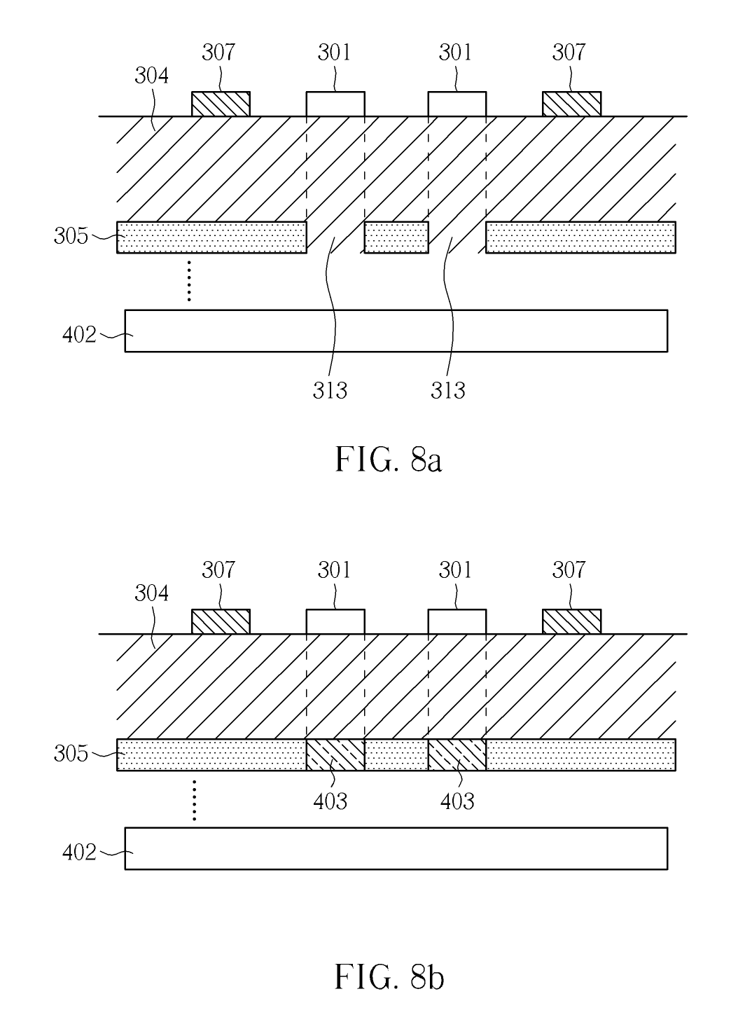

FIG. 7 illustrates a circuit board structure 700 according to a second embodiment of the present invention. The difference between the circuit board structure 700 and the circuit board structure 300 is: the cavity in the circuit board structure 300 is larger than the pad, but the cavity or the low capacitance region of the circuit board structure 700 is smaller or equals to the pad. If looks down to the circuit board structure 700, the cavity or the low capacitance region is covered by the pad, thus the cavity 313 is presented by dot lines. FIG. 8 (a), FIG. 8 (b), FIG. 9 (a) and FIG. 9 (b) respectively illustrates cross section view diagrams of the circuit board structure 700 shown in FIG. 7. FIGS. 8 (a) and 8 (b) illustrate a cross section view along the P direction, and FIGS. 9 (a) and 9 (b) illustrate a cross section view along the Q direction.

As shown in FIG. 8 (a) , sizes of the cavity 313 and the pad 301 are the same. Such structure can also be presented as: a vertical projection of the pad 301, which is projected on the first grounding copper foil 305, is totally overlapped with the cavity 313. FIG. 8 (b) illustrates the situation that the cavity 313 in FIG. 8 (a) is replaced by the low capacitance region 403. In FIG. 9 (a), the cavity 313 is smaller than the pad 301. Such structure can be presented as: a vertical projection of the pad 301, which is projected on the first grounding copper foil 305, includes the cavity 313. FIG. 9 (b) illustrates the situation that the cavity 313 in FIG. 9 (a) is replaced by the low capacitance region 403.

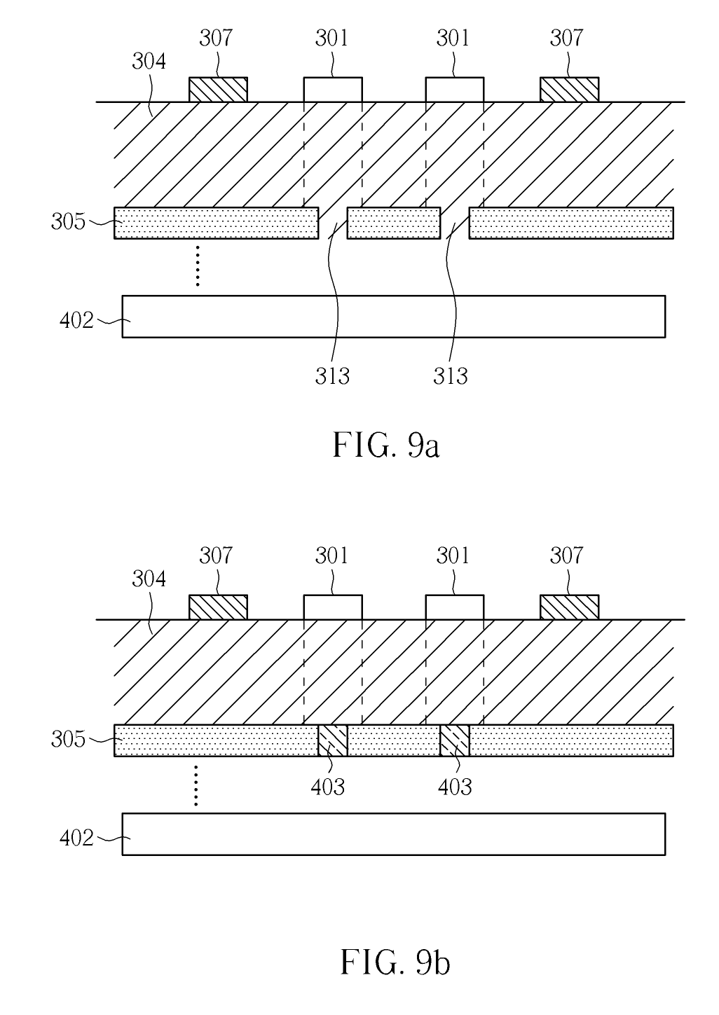

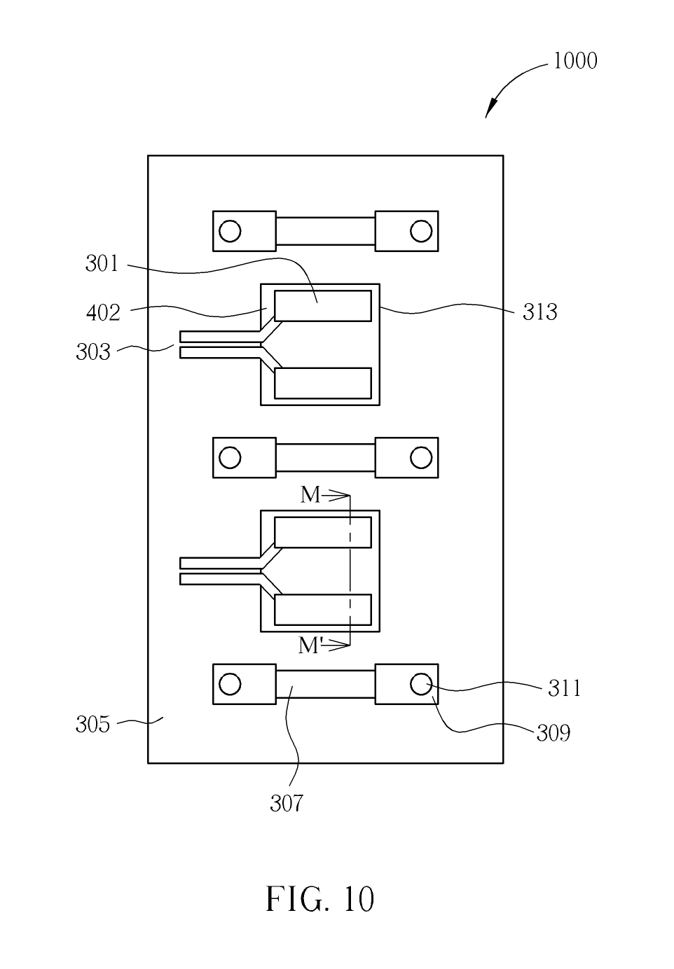

FIG. 10 illustrates a circuit board structure 1000 according to a third embodiment of the present invention. The difference between the circuit board structure 1000 and the circuit board structure 300 is: the cavity in the circuit board structure 300 is larger than the pad, smaller than two pads, but the cavity of the circuit board structure 1000 can comprise more than two pads. Accordingly, if looks down on the circuit board structure 1000, the same cavity 313 contains more than two pads 301.

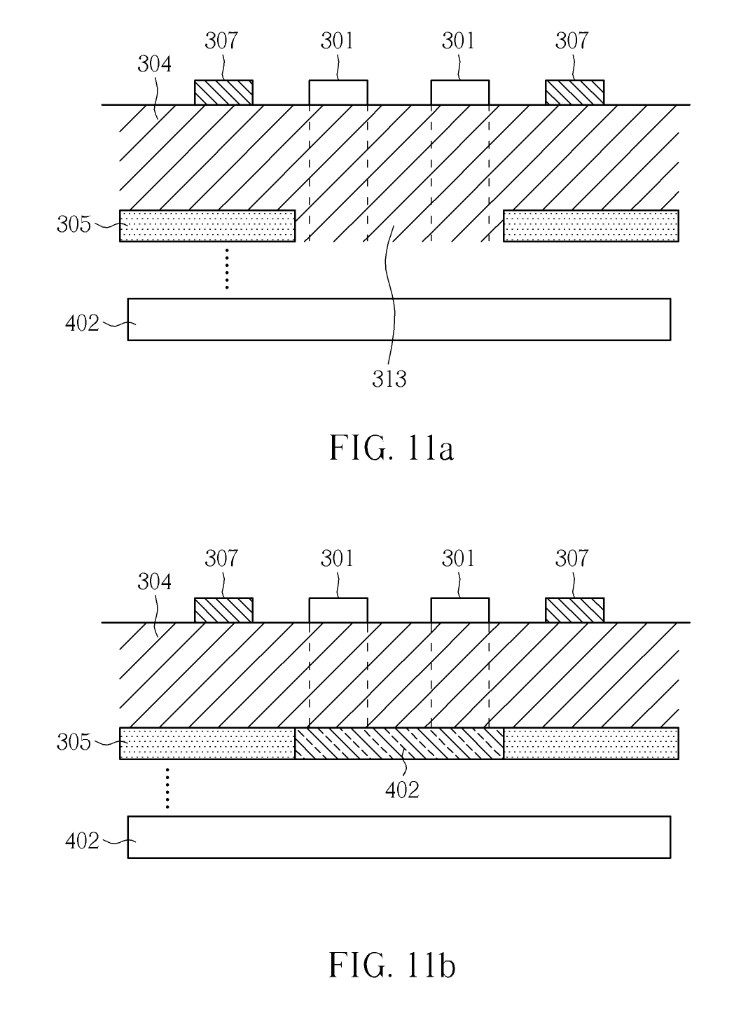

FIGS. 11 (a), 11 (b) illustrate the cross section view diagram of the circuit structure shown in FIG. 10. As shown in FIG. 11 (a), the cavity 313 includes a plurality of pads 301. Alternatively, it can be presented that each of the cavities 313 includes a plurality of vertical projections of the pad 301, which are projected on the first grounding copper foil 305. FIG. 11 (b) illustrates the situation that the cavity 313 in FIG. 9 (a) is replaced by the low capacitance region 403.

Via above-mentioned embodiments, the capacitance of the connection point for the connector an the circuit board can be decreased.

Those skilled in the art will readily observe that numerous modifications and alterations of the device and method may be made while retaining the teachings of the invention.

What is claimed is:

1. A circuit board structure, comprising:
a first metal layer, including at least one cavity; and
a plurality of first pads, for connecting at least one differential signal transmission line;
wherein at least part of a vertical projection of the first pad, which is projected on the first metal layer, is overlapped with the cavity.

2. The circuit board structure of claim 1, further comprising non conductive material, which is filled into the cavity and filled between the metal layer and the first pad.

3. The circuit board structure of claim 1, wherein a vertical projection of the first pad, which is projected on the first metal layer, is totally overlapped with the cavity.

4. The circuit board structure of claim 1, wherein a vertical projection of the first pad, which is projected on the first metal layer, is included in the cavity.

5. The circuit board structure of claim 1, wherein a vertical projection of the first pad, which is projected on the first metal layer, includes the cavity.

6. The circuit board structure of claim 1, wherein each of the cavities includes a plurality of vertical projections of the first pad, which are projected on the first metal layer.

7. The circuit board structure of claim 1, wherein the first metal layer is a grounding copper foil.

8. The circuit board structure of claim 7, further comprising a second metal layer, wherein the second metal layer is a grounding copper foil.

9. The circuit board structure of claim 1, further comprising:
a second pad; and
a contact;
wherein the second pad is electrically coupled to the first metal layer via the contact, and a distance between the contact and the second pad makes a voltage level of the second pad equals to which of the first metal layer.

10. The circuit board structure of claim 9, wherein the distance between the contact and the second pad is smaller than 500 mils.

11. A circuit board structure, comprising:
a first metal layer, including at least one low capacitance region; and
a plurality of first pads, for connecting at least one differential signal transmission line;
wherein at least part of a vertical projection of the first pad, which is projected on the first metal layer, is overlapped with the low capacitance region.

12. The circuit board structure of claim 11, further comprising non conductive material, which is filled into the low capacitance region and filled between the metal layer and the first pad.

13. The circuit board structure of claim 11, wherein a vertical projection of the first pad, which is projected on the first metal layer, is totally overlapped with the low capacitance region.

14. The circuit board structure of claim 11, wherein a vertical projection of the first pad, which is projected on the first metal layer, is included in the low capacitance region.

15. The circuit board structure of claim 11, wherein a vertical projection of the first pad, which is projected on the first metal layer, includes the low capacitance region.

16. The circuit board structure of claim 11, wherein each of the cavities includes a plurality of vertical projections of the first pad, which are projected on the first metal layer.

17. The circuit board structure of claim 11, wherein the first metal layer is a grounding copper foil.

18. The circuit board structure of claim 17, further comprising a second metal layer, wherein the second metal layer is a grounding copper foil.

19. The circuit board structure of claim 11, further comprising:
a second pad; and
a contact;
wherein the second pad is electrically coupled to the first metal layer via the contact, and a distance between the contact and the second pad makes a voltage level of the second pad equals to which of the first metal layer.

20. The circuit board structure of claim 19, wherein the distance between the contact and the second pad is smaller than 500 mils.
